(19) United States
(12) Patent Application Publication
(10) Pub. No.: US 2016/0035665 A1
(43) Pub. Date: Feb. 4, 2016

(54) CIRCUIT ARRANGEMENT AND METHOD FOR MANUFACTURING THE SAME

(71) Applicant: Infineon Technologies AG, Neubiberg (DE)

(72) Inventors: Ralf OTREMBA, Kaufbeuren (DE); Klaus SCHIESS, Allensbach (DE); Anton MAUDER, Kolbermoor (DE)

(21) Appl. No.: 14/450,300

(22) Filed: Aug. 4, 2014

(51) Int. Cl. H01L 23/498; H01L 23/31

(52) U.S. Cl. CPC H01L 23/49844; H01L 23/3114

(57) ABSTRACT

A circuit arrangement is provided, which may include: an embedding package chip carrier; a first chip and a second chip arranged over the embedding package chip carrier, each of the first chip and the second chip comprising: a control terminal, a first controlled terminal, and a second controlled terminal, wherein the control terminal and the first controlled terminal are arranged on a first side of the chip, and wherein the second controlled terminal is arranged on a second side of the chip, wherein the second side is opposite the first side; wherein the first chip is arranged on the embedding package chip carrier such that its first side is facing towards the embedding package chip carrier; and wherein the second chip is arranged on the embedding package chip carrier such that its first side is facing away from the embedding package chip carrier.

### TECHNICAL FIELD

Various embodiments relate generally to a circuit arrangement and to a method for manufacturing a circuit arrangement.

### BACKGROUND

Integrated circuit chips may be integrated into a circuit arrangement. A plurality of integrated circuit chips may for example be arranged to form a cascode or a half-bridge. Various discrete components/packages (e.g. transistor outline packages TO247-3) may be mounted on an application board (e.g. AC/DC converter or DC/DC converter) to form a cascode type circuit arrangement. Here, a creepage distance may be determined by geometries of the individual components/packages and distances between them.

However, chip embedding may currently only be suitable for low voltage applications (<200 V), because the creepage distances depend on surfaces of the chips and typically measure around 1 mm.

### SUMMARY

Various embodiments may provide a circuit arrangement. The circuit arrangement may include an embedding package chip carrier; a first chip and a second chip arranged over the embedding package chip carrier, each of the first chip and the second chip including: a control terminal, a first controlled terminal, and a second controlled terminal, wherein the control terminal and the first controlled terminal are arranged on a first side of the chip, and wherein the second controlled terminal is arranged on a second side of the chip, wherein the second side is opposite the first side; wherein the first chip is arranged on the embedding package chip carrier such that its first side is facing towards the embedding package chip carrier; and wherein the second chip is arranged on the embedding package chip carrier such that its first side is facing away from the embedding package chip carrier.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a side view of a chip in accordance with various embodiments;

FIGS. 2A and 2B show a circuit arrangement according to various embodiments;

FIG. 3 shows a circuit arrangement according to various embodiments;

FIG. 4 shows a circuit arrangement according to various embodiments.

FIG. 5 shows a circuit diagram corresponding to the circuit arrangement of FIG. 2A, FIG. 2B and of FIG. 3.

FIG. 6 shows a flowchart illustrating a method for manufacturing a circuit arrangement according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

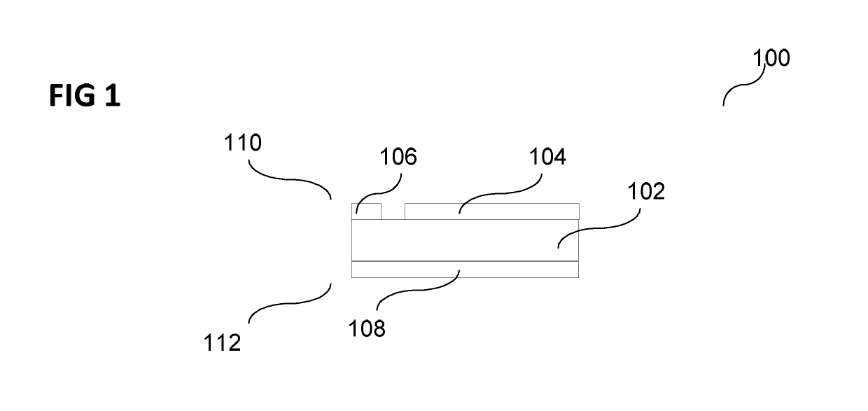

FIG. 1 shows a side view of a chip 100 in accordance with various embodiments. The chip 100 may include a first side 110 and a second side 112. The second side 112 may be opposite the first side 110. An optional control terminal 106 and a first controlled terminal 104 may be arranged on the first side 110 of the chip 100, and a second controlled terminal 108 may be arranged on the second side 112 of the chip 100.

In various embodiments, the chip 100 may be a power chip. In various embodiments, the chip 100 may be a power chip selected from the group consisting of power FET (field effect transistor, such as power MOSFET (Metal Oxide Semiconductor Field Effect Transistor) or JFET (Junction Gate Field Effect Transistor)); power bipolar transistor; IGBT (Insulated Gate Bipolar Transistor); thyristor and power diode. In various embodiments, the power chip may include a power FET integrated with additional logic and/or sensor components using BCD (Bipolar-CMOS-DMOS) technology or CD (CMOS-DMOS) technology or SOI (Silicon On Insulator) technology.

In various embodiments, a load current may flow vertically through the chip 100 from the first side 110 of the chip to the second side 112 of the chip 100 or vice versa. In other words, the load current can flow in a direction perpendicular to the first side 110 and the second side 112 of the chip. According to embodiments, additional control and/or sensing currents may either flow vertically and/or laterally through the chip 100. In other words, the control and/or sensing currents can be partitioned in control and/or sense currents flowing perpendicular to the first side 110 or parallel to the first side 110 of the chip, wherein the partitioning may include fully parallel and fully perpendicular.

In various embodiments, the control terminal 106 and the first controlled terminal 104 may for example be a gate terminal and a source terminal, respectively, of a power MOSFET chip, and the second controlled terminal 112 may be a drain terminal of the power MOSFET chip. In this way, the terminals of the MOSFET chip may be arranged so as to support a vertical current flow through the chip 100 between the source terminal over the first side 110 of the chip and the drain terminal over the second side 112 of the chip.

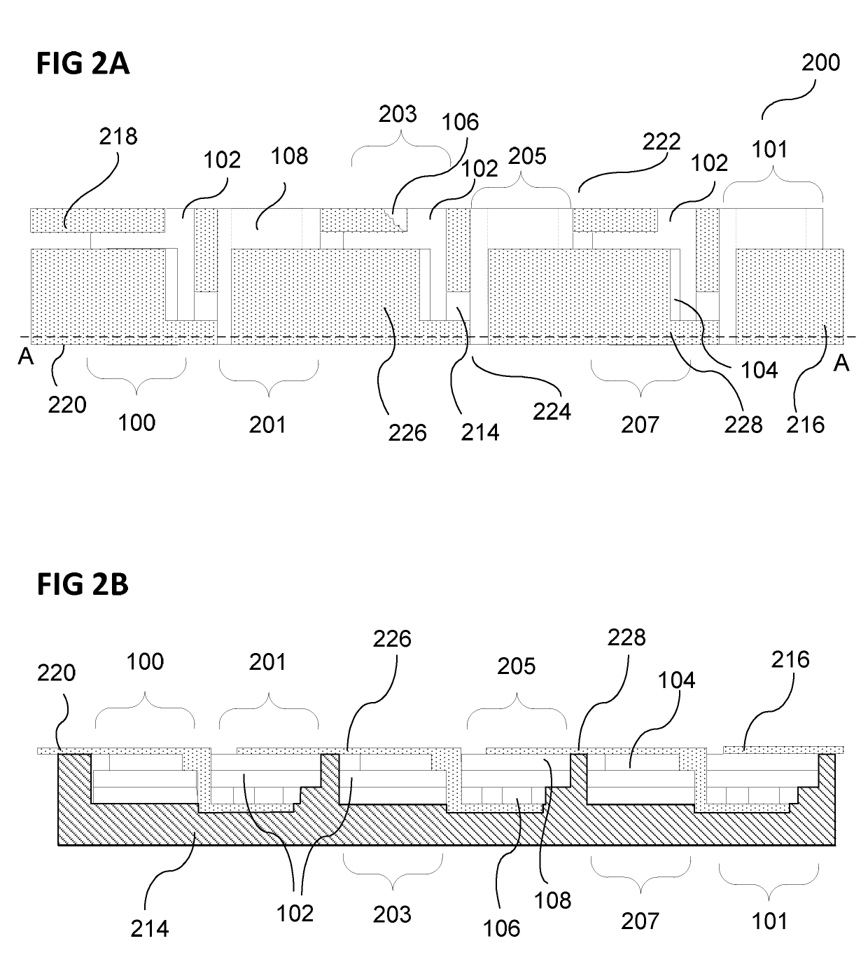

FIGS. 2A and 2B show a circuit arrangement according to various embodiments. FIG. 2A shows a top view of the circuit arrangement, and FIG. 2B shows a cross section along the line A-A in FIG. 2A.

Even though a circuit arrangement including six chips is shown in FIG. 2A and FIG. 2B, the circuit arrangement may include any number of chips, with a minimum of two chips.

In various embodiments, a first chip 100 and a second chip 101 may be arranged over an embedding package chip carrier (also referred to as “carrier”) 214. The chips 100 and 101 may be chips as described in connection with FIG. 1.

In various embodiments, the carrier 214 may be a printed circuit board. In various embodiments, the carrier 214 may include an organic material, for example an organic substrate, e.g., including laminate material or epoxy. In various embodiments, the embedding package chip carrier may include a laminate filled with glass fiber. In various embodiments, the carrier 214 may include an inorganic substrate, e.g. including ceramic material.

In various embodiments, the first chip 100 and the second chip 101 may be embedded into the embedding package chip carrier 214. In various embodiments, the chip 100 and the chip 101 may be partially embedded into the embedding package chip carrier 214. In various embodiments, one of the first chip 100 and the second chip 101 may be embedded into the embedding package chip carrier 214, and the other chip may be partially embedded into the embedding package chip carrier 214.

In various embodiments, the first chip 100 may be arranged on the embedding package chip carrier 214 such that its first side 110 is facing towards the embedding package chip carrier 214, and the second chip 101 may be arranged on the embedding package chip carrier 214 such that its first side 110 is facing away from the embedding package chip carrier 214.

Furthermore, in various embodiments, the first chip 100 and the second chip 102 may be arranged on the embedding package chip carrier 214 such that one of the first chip 100 and the second chip 101 is rotated by 180°, with respect to the other one of the first chip 100 and the second chip 101, around an axis that is orthogonal to the first side 110 and the second side 112 of the chip.

FIG. 2A shows an example of such an arrangement including six chips, wherein the invention is not meant to be limited to this number of chips. Whereas the first chip 100, a third chip 203 and a fifth chip 207 (counting from the left) may be arranged on the embedding package chip carrier 214 in such a way that their control terminal 106 is facing away from the embedding package chip carrier, and that it is pointing towards an edge (a lateral side) 222 of the chip carrier, the second chip 101 (arranged on a sixth position counting from the left) and the chips 201 and 205 (arranged on second and fourth positions, respectively, counting from the left) are arranged on the embedding package chip carrier 214 in such a way that their control terminal 106 is facing towards the embedding package chip carrier, and that it is pointing towards an edge (a lateral side) 224 opposite the edge 222 of the chip carrier 214.

In various embodiments, the arrangement with the first chip 100 arranged on the embedding package chip carrier 214 such that its first side 110 is facing towards the embedding package chip carrier 214, and the second chip 101 arranged on the embedding package chip carrier 214 such that its first side 110 is facing away from the embedding package chip carrier 214 may facilitate an electrical coupling of the chips for forming a desired circuit arrangement, for example a cascode circuit arrangement.

In various embodiments, at least one of the terminals 104, 106, 108 of the first chip 100 may be electrically coupled with at least one terminal 104, 106, 108 of the second chip 101 via a contact structure 216, 218, 220.

In various embodiments, the first controlled terminal 104 of the first chip 100 may be electrically coupled with the control terminal 106 of the second chip 101 via the contact structure 220. The second controlled terminal 108 of the first chip 100 may be electrically coupled with the first controlled terminal of the second chip.

In various embodiments, the second controlled terminal 108 of the chip 201, arranged on second position counting from the left, may be electrically coupled with the first controlled terminal 104 of the third chip 203 and with the control terminal 106 of the chip 205, arranged on the fourth position counting from the left, via a contact structure 226. The first controlled terminal 104 of the chip 201 may be electrically coupled with the control terminal 106 of the first chip 100.

In various embodiments, the contact structure 216, 218, 220 may provide connection terminals for external connection of the circuit arrangement.

In various embodiments, the contact structure 216, 218, 220, 226, 228 may include a galvanic contact structure.

In various embodiments, the contact structure 216, 218, 220 may include a cascode.

In various embodiments, the contact structure 216, 218, 220 may include a half-bridge circuit structure.

In various embodiments, the individual chips, for example individual MOS-chips, may be arranged on the embedding package chip carrier 214 as described above. They may be embedded within the embedding package chip carrier 214, and the electrical coupling may be performed within the embedding package chip carrier 214. In this way, it may be possible to obtain a desired increase in creepage distance, for example in the creepage distance between the first controlled terminal 104 and the second controlled terminal 108. For the example of MOS-chips, those terminals may correspond to a source and a drain terminal, respectively.

In various embodiments, the creepage distance between the control terminal and the second controlled terminal and between the first controlled terminal and the second controlled terminal may be larger than about 5 mm, for example larger than about 10 mm.

The circuit arrangement according to various embodiments may create fewer losses, i.e. energy losses. It may be slower, i.e. its reaction and/or transition time at switching may be longer compared to a single chip capable to block the same voltage, which, however, is acceptable e.g. for battery switches.

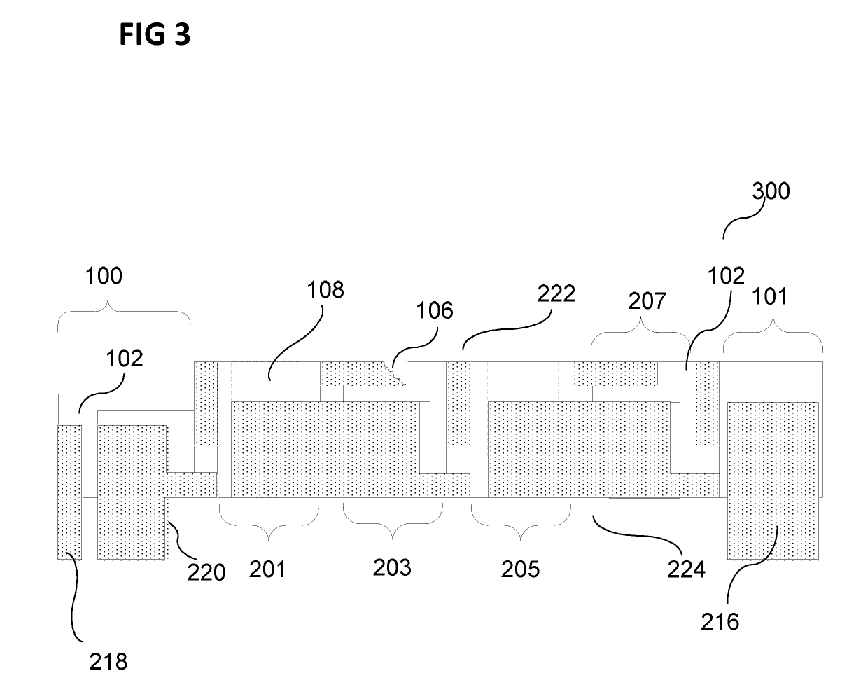

FIG. 3 shows a circuit arrangement 300 according to various embodiments.

Even though a circuit arrangement 300 including six chips is shown in FIG. 3, the circuit arrangement may include any number of chips, with a minimum of two chips.

The circuit arrangement 300 shown in FIG. 3 is similar to the circuit arrangement 200 shown in FIG. 2A and FIG. 2B, with the difference that a chip providing connection terminals, which may be one of the first chip 100 and the second chip 101, and which may be a first or a last chip in a row of chips, may be arranged differently than in FIG. 2A and in FIG. 2B. In various embodiments, said first chip 100 or second chip 101 may be arranged on the embedding package chip carrier 214 such that it is rotated by 90°, with respect to the other one of the first chip 100 and the second chip 101, around an axis that is orthogonal to the first side 110 and the second side 112 of the chip.

Such an arrangement may, in various embodiments, facilitate an arrangement of all connection terminals on one side, for example on one lateral side 224, of the circuit arrangement.

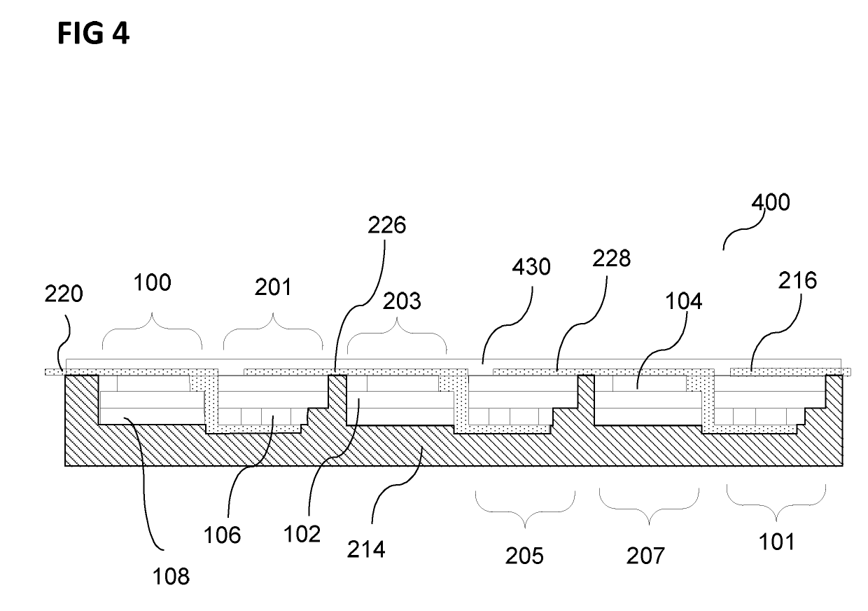

FIG. 4 shows a circuit arrangement 400 according to various embodiments.

The circuit arrangement 400 of FIG. 4 is substantially similar to the circuit arrangement 200 of FIG. 2A and FIG. 2B.

However, it differs from the circuit arrangement 200 in that in various embodiments, encapsulation material 430 may be formed over at least a portion of the first chip 100 and the second chip 101. In various embodiments, the circuit arrangement 400 may be encapsulated with encapsulation material. The encapsulation material 430 may for example include mold material (e.g. press mold material), lamination material (e.g. polymer material with glass fibers), or anorganic material such as e.g. a ceramic material.

In various embodiments, the contact structure 216, 218, 220 may include a galvanic redistribution structure formed on the encapsulation material 430 that may be formed over at least a portion of the first chip 100 and the second chip 101.

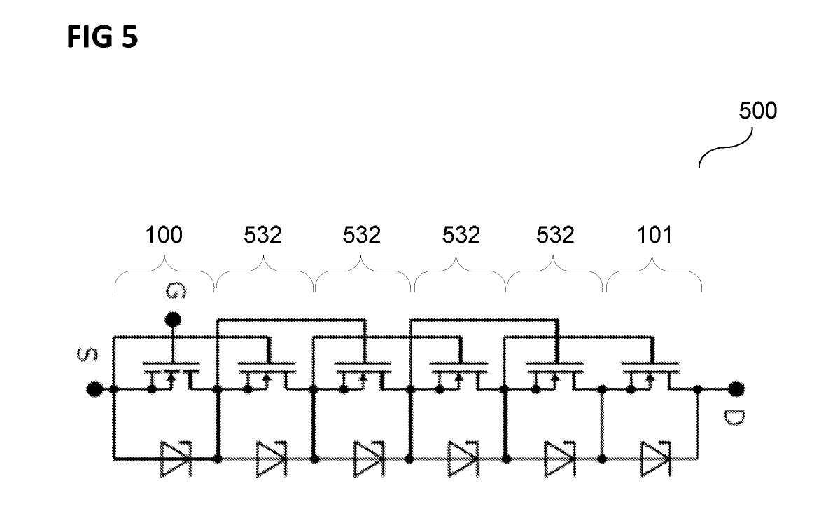

FIG. 5 shows a circuit diagram corresponding to the circuit arrangement of FIG. 2A, FIG. 2B, FIG. 3 and FIG. 4.

In various embodiments, the circuit 500 may be a cascode-like circuit formed by a plurality of chips 100, 101 of the circuit arrangements 200, 300 or 400, and the further chips 532. In various embodiments, the first chip 100 may be a normally-off device, such as an enhancement MOS component, and the second chip and further chips 101, 532 may be normally-on devices, such as depletion MOS components. In various embodiments, the circuit diagrams of the first chips 100 and/or the second chips 101 and/or the further chips 532 may be read in a way that the voltage limiting elements and/or diodes placed in parallel, for example connected in parallel, to the respective MOS components may be regarded as being monolithically integrated in the respective MOS components and/or being placed as additional chips in parallel, for example connected as additional chips in parallel, to the respective MOS component on the circuit arrangements 200, 300 or 400. In various further embodiments, the additional chips may differ from diodes and/or voltage limiting elements and may comprise power chips selected from the group consisting of power FET (field effect transistor, such as power MOSFET (Metal Oxide Semiconductor Field Effect Transistor) or JFET (Junction Gate Field Effect Transistor)); power bipolar transistor; IGBT (Insulated Gate Bipolar Transistor); thyristor; and sensing or control chips. Depending on the requirement with respect to the electrical strength, an arbitrary number (e.g. 5 to 10) of depletion MOS components may be included in the circuit arrangement 200, 300 or 400, wherein the total electric strength results from the sum of the individual electric strengths.

In various embodiments, not the entire circuit 500 of FIG. 5 needs to be included in the circuit arrangement 200, 300 or 400. For example, only part of the circuit 500 of FIG. 5 may be included in the circuit arrangement 200, 300 or 400.

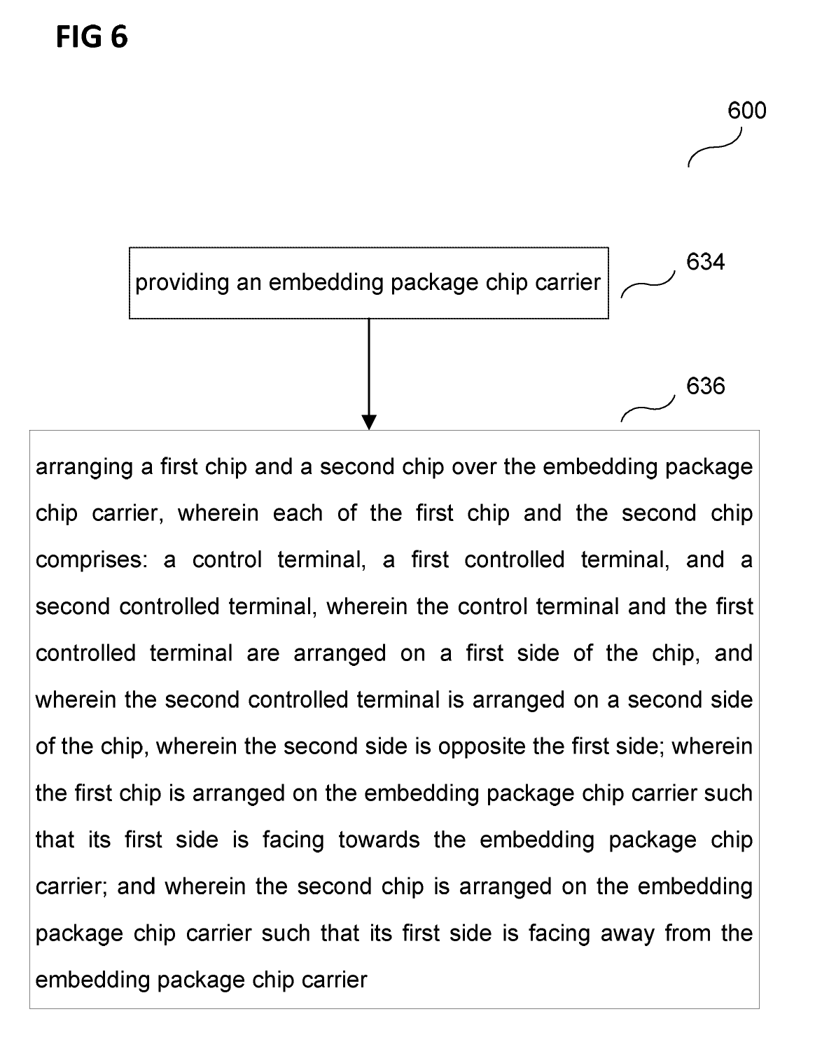

FIG. 6 shows a flowchart 600 illustrating a method for manufacturing a circuit arrangement according to various embodiments.

At 634, an embedding package chip carrier may be provided.

At 636, a first chip and a second chip may be arranged over the embedding package chip carrier, wherein each of the first chip and the second chip may include: a control terminal, a first controlled terminal, and a second controlled terminal, wherein the control terminal and the first controlled terminal may be arranged on a first side of the chip, and wherein the second controlled terminal may be arranged on a second side of the chip, wherein the second side may be opposite the first side; wherein the first chip may be arranged on the embedding package chip carrier such that its first side is facing towards the embedding package chip carrier; and wherein the second chip may be arranged on the embedding package chip carrier such that its first side is facing away from the embedding package chip carrier.

In various embodiments, the chip may be a power chip. In various embodiments, the chip may be a power chip selected from the group consisting of power FET (field effect transistor, such as power MOSFET (Metal Oxide Semiconductor Field Effect Transistor) or JFET (Junction Gate Field Effect Transistor)); power bipolar transistor; IGBT (Insulated Gate Bipolar Transistor); thyristor; and power diode. In various embodiments, the power chip may include a power FET integrated with additional logic and/or sensor components using BCD (Bipolar-CMOS-DMOS) technology or CD (CMOS-DMOS) technology or SOI (Silicon On Insulator) technology.

In various embodiments, a load current may flow vertically through the chip from the first side of the chip to the second side of the chip or vice versa. In other words, the load current can flow in a direction perpendicular to the first side and the second side of the chip.

In various embodiments, the control terminal and the first controlled terminal may for example be a gate terminal and a source terminal, respectively, of a power MOSFET chip, and the second controlled terminal may be a drain terminal of the power MOSFET chip. In this way, the terminals of the MOSFET chip may be arranged so as to support a vertical current flow through the chip between the source terminal over the first side of the chip and the drain terminal over the second side of the chip.

In various embodiments, the carrier may be a printed circuit board. In various embodiments, the carrier may include an organic material, for example an organic substrate, e.g., including laminate material or epoxy. In various embodiments, the embedding package chip carrier may include a laminate filled with glass fiber. In various embodiments, the carrier may include an inorganic substrate, e.g. including ceramic material. wherein the embedding package chip carrier includes a laminate.

In various embodiments, arranging of the first chip and the second chip over the embedding package chip carrier may include embedding into the embedding package chip carrier. In various embodiments, the chip and the chip may be partially embedded into the embedding package chip carrier. In various embodiments, one of the first chip and the second chip may be embedded into the embedding package chip carrier, and the other chip may be partially embedded into the embedding package chip carrier.

In various embodiments, arranging of the first chip and the second chip over the embedding package chip carrier may include arranging the first chip on the embedding package chip carrier such that its first side is facing towards the embedding package chip carrier, and arranging the second chip on the embedding package chip carrier such that its first side is facing away from the embedding package chip carrier.

Furthermore, in various embodiments, arranging of the first chip and the second chip over the embedding package chip carrier may include arranging the first chip and the second chip on the embedding package chip carrier such that one of the first chip and the second chip is rotated by 90 or 180°, with respect to the other one of the first chip and the second chip, around an axis that is orthogonal to the first side and the second side of the chip.

In various embodiments, arranging the first chip on the embedding package chip carrier such that its first side is facing towards the embedding package chip carrier, and arranging the second chip on the embedding package chip carrier such that its first side is facing away from the embedding package chip carrier may facilitate an electrical coupling of the chips for forming a desired circuit arrangement, for example a cascode circuit arrangement.

In various embodiments, at least one of the terminals of the first chip may be electrically coupled with at least one terminal of the second chip via a contact structure.

In various embodiments, the first controlled terminal of the first chip may be electrically coupled with the control terminal of the second chip via the contact structure.

The second controlled terminal of the first chip may be electrically coupled with the first controlled terminal of the second chip.

In various embodiments, the second controlled terminal of the second chip may be electrically coupled with a first controlled terminal of a third chip and with a control terminal of a fourth chip via a contact structure. The first controlled terminal of the second chip may be electrically coupled with the control terminal of the first chip.

In various embodiments, the contact structure may provide connection terminals for external connection of the circuit arrangement.

In various embodiments, the contact structure may include a galvanic contact structure.

In various embodiments, the contact structure may include a cascode.

In various embodiments, the contact structure may include a half-bridge.

In various embodiments, arranging of the first chip and the second chip may, for example, include arranging MOS-chips on the embedding package chip carrier as described above. Arranging of the first chip and the second chip may include embedding the chips within the embedding package chip carrier, and the electrical coupling may be performed within the embedding package chip carrier. In this way, it may be possible to obtain a desired increase in creepage distance, for example in the creepage distance between the first controlled terminal and the second controlled terminal. For the example of MOS-chips, those terminals may correspond to a source and a drain terminal, respectively.

In various embodiments, the creepage distance between the control terminal and the second controlled terminal and between the first controlled terminal and the second controlled terminal may be larger than about 5 mm, for example larger than about 10 mm.

The circuit arrangement according to various embodiments may create fewer losses, i.e. energy losses. It may be slower, i.e. its reaction and/or transition time at switching may be longer compared to a single chip capable to block the same voltage may be longer, which, however, is acceptable e.g. for battery switches.

In various embodiments, the method for manufacturing a circuit arrangement may further include forming encapsulation material over at least a portion of the first chip and the second chip. In various embodiments, forming encapsulation material over at least a portion of the first chip and the second chip may include encapsulating the circuit arrangement with encapsulation material. The encapsulation material may for example include mold material (e.g. press mold material), lamination material (e.g. polymer material with glass fibers), or anorganic material such as e.g. a ceramic material.

In various embodiments, the contact structure may include a galvanic redistribution structure formed on the encapsulation material that may be formed over at least a portion of the first chip and the second chip.

In various embodiments, the first chip may be a normally-off device, such as an enhancement MOS component, and the second chip and further chips may be normally-on devices, such as depletion MOS components. Depending on the requirement with respect to the electrical strength, an arbitrary number (e.g. 5 to 10) of depletion MOS components may be included in the circuit arrangement wherein the total electric strength results from the sum of the individual electric strengths.

Various embodiments described with respect to the circuit arrangements 200, 300, 400 or 500 above are analogously valid for the method of manufacturing the circuit arrangement of FIG. 6.

In various embodiments, a circuit arrangement is provided. The circuit arrangement may include: an embedding package chip carrier; a first chip and a second chip arranged over the embedding package chip carrier, each of the first chip and the second chip comprising: a control terminal, a first controlled terminal, and a second controlled terminal, wherein the control terminal and the first controlled terminal are arranged on a first side of the chip, and wherein the second controlled terminal is arranged on a second side of the chip, wherein the second side is opposite the first side; wherein the first chip is arranged on the embedding package chip carrier such that its first side is facing towards the embedding package chip carrier; and wherein the second chip is arranged on the embedding package chip carrier such that its first side is facing away from the embedding package chip carrier.

In various embodiments, the embedding package chip carrier may include a laminate or a laminate filled with glass fiber. In various embodiments, the embedding package chip carrier may include an organic material. In various embodiments, at least one of the terminals of the first chip may be electrically coupled with at least one terminal of the second chip via a contact structure. In various embodiments, the contact structure may include a galvanic contact structure. In various embodiments, the contact structure may include a galvanic redistribution structure formed on encapsulation material that is formed over at least a portion of the first chip and the second chip. In various embodiments, the encapsulation material may include a laminate or anorganic material such as e.g. a ceramic material. In various embodiments, the creepage distance between the control terminal and the second controlled terminal and between the first controlled terminal and the second controlled terminal may be larger than 5 mm. In various embodiments, the creepage distance between the control terminal and the second control terminal and between the first controlled terminal and the second controlled terminal may be around 10 mm. In various embodiments, the contact structure may include a cascode or a half-bridge. In various embodiments, a load current may flow between the first controlled terminal and the second controlled terminal. In various embodiments, the first chip may be a power semiconductor chip.

In various embodiments, a method for manufacturing a circuit arrangement is provided. The method may include: providing an embedding package chip carrier; arranging a first chip and a second chip over the embedding package chip carrier, wherein each of the first chip and the second chip may include: a control terminal, a first controlled terminal, and a second controlled terminal, wherein the control terminal and the first controlled terminal may be arranged on a first side of the chip, and wherein the second controlled terminal may be arranged on a second side of the chip, wherein the second side is opposite the first side; wherein the first chip may be arranged on the embedding package chip carrier such that its first side is facing towards the embedding package chip carrier; and wherein the second chip may be arranged on the embedding package chip carrier such that its first side is facing away from the embedding package chip carrier.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A circuit arrangement, comprising:
an embedding package chip carrier;
a first chip and a second chip arranged over the embedding package chip carrier, each of the first chip and the second chip comprising:
a control terminal,
a first controlled terminal, and
a second controlled terminal,
wherein the control terminal and the first controlled terminal are arranged on a first side of the chip, and
wherein the second controlled terminal is arranged on a second side of the chip, wherein the second side is opposite the first side;
wherein the first chip is arranged on the embedding package chip carrier such that its first side is facing towards the embedding package chip carrier; and
wherein the second chip is arranged on the embedding package chip carrier such that its first side is facing away from the embedding package chip carrier.

2. The circuit arrangement of claim 1,
wherein the embedding package chip carrier comprises a laminate.

3. The circuit arrangement of claim 2,
wherein the embedding package chip carrier comprises a laminate filled with glass fiber.

4. The circuit arrangement of claim 1,
wherein the embedding package chip carrier comprises an organic material.

5. The circuit arrangement of claim 1,
wherein at least one of the terminals of the first chip is electrically coupled with at least one terminal of the second chip via a contact structure.

6. The circuit arrangement of claim 5,
wherein the contact structure comprises a galvanic contact structure.

7. The circuit arrangement of claim 5,
wherein the contact structure comprises a galvanic redistribution structure formed on encapsulation material that is formed over at least a portion of the first chip and the second chip.

8. The circuit arrangement of claim 7,
wherein the encapsulation material comprises a laminate or anorganic material such as e.g. a ceramic material.

9. The circuit arrangement of claim 1,
wherein the creepage distance between the control terminal and the second controlled terminal and between the first controlled terminal and the second controlled terminal is larger than 5 mm.

10. The circuit arrangement of claim 9,
wherein the creepage distance between the control terminal and the second control terminal and between the first controlled terminal and the second controlled terminal is around 10 mm.

11. The circuit arrangement of claim 5,
wherein the contact structure comprises a cascode.

12. The circuit arrangement of claim 5,
wherein the contact structure comprises a half-bridge.

13. The circuit arrangement of claim 1,
wherein a load current flows between the first controlled terminal and the second controlled terminal.

14. The circuit arrangement of claim 1,
wherein the first chip is a power semiconductor chip.

15. A method for manufacturing a circuit arrangement, the method comprising:
providing an embedding package chip carrier;
arranging a first chip and a second chip over the embedding package chip carrier, wherein each of the first chip and the second chip comprises:
a control terminal,
a first controlled terminal, and
a second controlled terminal,
wherein the control terminal and the first controlled terminal are arranged on a first side of the chip, and
wherein the second controlled terminal is arranged on a second side of the chip, wherein the second side is opposite the first side;
wherein the first chip is arranged on the embedding package chip carrier such that its first side is facing towards the embedding package chip carrier; and
wherein the second chip is arranged on the embedding package chip carrier such that its first side is facing away from the embedding package chip carrier.
